(19) United States
(12) Patent Application Publication
(10) Pub. No.: US 2015/0097605 A1
(43) Pub. Date: Apr. 9, 2015

(54) DUTY CORRECTION CIRCUIT AND METHOD

(71) Applicant: SK hynix Inc., Gyeonggi-do (KR)

(72) Inventors: Dong-Suk SHIN, Gyeonggi-do (KR); Hyun-Woo LEE, Gyeonggi-do (KR)

(73) Assignee: SK hynix Inc., Gyeonggi-do (KR)

(21) Appl. No.: 14/106,793

(22) Filed: Dec. 15, 2013

(30) Foreign Application Priority Data
Oct. 8, 2013 (KR) 10-2013-0119729

(51) Int. Cl. H03K 3/017

(52) U.S. Cl. CPC H03K 3/017
USPC 327/175

(57) ABSTRACT

A duty correction circuit includes a duty ratio control unit suitable for generating an output clock by adjusting the duty ratio of an input clock, a code generation unit suitable for detecting a duty of the output clock and generating a first duty ratio control code based on the detection result, and a code filter unit suitable for providing the duty ratio control unit with a second duty ratio control code corresponding to a target value when a value of the first duty ratio control code is within a predetermined critical range adjacent to the target value.

### CROSS-REFERENCE TO RELATED APPLICATIONS

The present application claims priority of Korean Patent Application No. 10-2013-0119729, filed on Oct. 8, 2013, which is incorporated herein by reference in its entirety.

### BACKGROUND

1. Field

Exemplary embodiments of the present invention relate to semiconductor design technology, and more particularly, to a duty correction circuit (DCC).

2. Description of the Related Art

In semiconductor devices operating based on a clock, such as synchronous memory devices, to accurately control the duty ratio of a clock is very important. For example, if the duty ratio of a clock is 50%, it means that a high pulse section and a low pulse section of the clock have the same width.

In the synchronous memory devices, data needs to be input/output in accurate synchronism with the rising edge and the falling edge of a clock. If the duty ratio of a clock does not accurately become 50%, timing between the rising edge and the falling edge of the clock is twisted, and thus data may not be input/output at accurate timings. For this reason, in the synchronous memory devices, a duty correction circuit (DCC) is used to accurately set the duty ratio of a clock to 50%.

A conventional DCC controls the duty ratio of a clock by using digital code. If the duty ratio of a clock is close to 50%, however, the digital code ‘0’ or ‘1’ may be updated. Accordingly, the duty ratio goes up and down on the basis of the duty ratio of 50%. That is, there may be a concern in that duty ratio of a clock is distorted because the duty ratio is subject to bang-bang in a range of 49% to 51%.

### SUMMARY

Various embodiments of the present invention are directed to a DCC capable of preventing the duty ratio of a clock from being twisted due to a bang-bang phenomenon, and a semiconductor device including the same.

In accordance with an embodiment of the present invention, a duty correction circuit may include a duty ratio control unit suitable for generating an output clock by adjusting the duty ratio of an input clock, a code generation unit suitable for detecting a duty of the output clock and generating a first duty ratio control code based on the detection result, and a code filter unit suitable for providing the duty ratio control unit with a second duty ratio control code corresponding to a target value when a value of the first duty ratio control code is within a predetermined critical range adjacent to the target value.

In accordance with another embodiment of the present invention, a duty ratio duty correction method may include detecting a duty of an output clock, generating a first duty ratio control code based on the detection result, outputting a second duty ratio control code corresponding to a target value when a value of the first duty ratio control code is within a predetermined critical range adjacent to the target value, and adjusting the duty ratio of an input clock based on the second duty ratio control code and outputting the adjusted clock as the output clock.

### BRIEF DESCRIPTION OF THE DRAWINGS

FIG. 1 is a block diagram illustrating a DCC in accordance with an embodiment of the present invention.

FIG. 2A is graph showing a duty ratio correction range according to a code in a conventional DCC.

FIG. 2B is graph showing a duty ratio correction range according to a code in a DCC in accordance with an embodiment of the present invention.

FIG. 3 is a detailed diagram of a code filter unit shown in FIG. 1.

FIG. 4 is a flowchart for explaining an operation of DCC shown in FIG. 1.

FIG. 5 is a flowchart or explaining an operation of a code Filter unit shown in FIGS. 1 and 3.

FIG. 6 is a block diagram illustrating a semiconductor device including the DCC in accordance with an embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, reference numerals correspond directly to the like numbered parts in the various figures and embodiments of the present invention. It is also noted that in this specification, “connected/coupled” refers to one component not only directly coupling another component but also indirectly coupling another component through an intermediate component. In addition, a singular form may include a plural form as long as it is not specifically mentioned in a sentence.

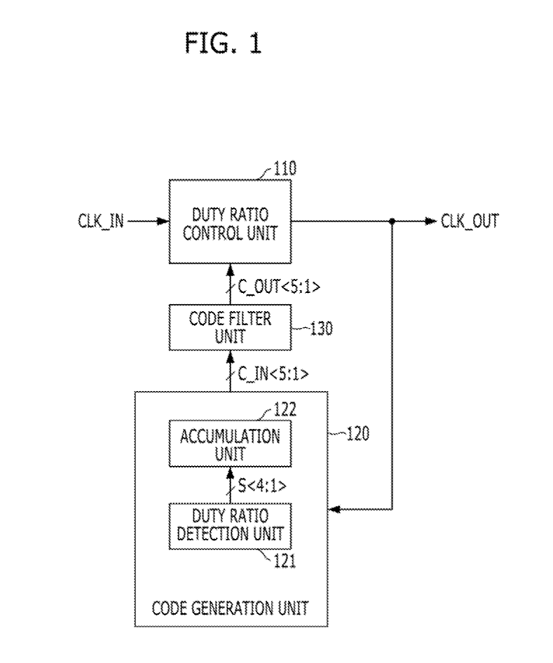

FIG. 1 is a block diagram illustrating a DCC in accordance with an embodiment of the present invention.

Referring to FIG. 1, the DCC may include a duty ratio control unit 110, a code generation unit 120, and a code filter unit 130.

The duty ratio control unit 110 may generate an output clock CLK_OUT by adjusting the duty ratio of an input clock CLK_IN in response to a second duty ratio control code C_OUT<5:1> output from the code filter unit 130.

The code generation unit 120 may detect a difference between a width of a high pulse section and a width of a low pulse section of the output clock CLK_OUT (i.e., detect a duty of the output clock CLK_OUT) and may generate a first duty ratio control code C_IN<5:1> based on the detection result.

The code generation unit 120 may include a duty ratio detection unit 121 and an accumulation unit 122.

The duty ratio detection unit 121 detects the difference between a width of a high pulse section and a width of a low pulse section of the output clock CLK_OUT every update cycle and determines a value of a duty ratio detection code S<4:1> corresponding to the detected value. The value of the duty ratio detection code S<4:1> corresponding to the width difference indicate the degree that the duty ratio of the output clock CLK_OUT is twisted. Furthermore, the duty ratio detection unit 121 detects which one of the width of the high pulse section and the width of the low pulse section is greater and detects the degree of the width difference, that is, up/down information. The up/down information may indicate that how much and in which direction the duty ratio of the output clock CLK_OUT is twisted. The duty ratio detection code S<4:1> includes the up/down information.

The accumulation unit 122 generates the first duty ratio control code C_IN<1:5> by accumulating the values of the duty ratio detection code S<4:1> output from the duty ratio detection unit 121. That is, the duty ratio detection code S<4:1> output every update cycle may be added up or subtracted. Whether the duty ratio detection code S<4:1> is to be added up or subtracted is determined based on up/down information.

In an ideal operation, since complete information necessary to correct the duty ratio of a clock may be output from the duty ratio detection unit 121, the duty ratio of a clock may be completely corrected based on the information from the duty ratio detection unit 121 through one duty ratio correction operation. If the duty ratio of a clock is greatly twisted, however, it may be impossible to fully correct the duty ratio of a clock through one duty ratio correction operation. Furthermore, even after the duty ratio of a clock is corrected, the duty ratio may be twisted again due to various factors.

The accumulation unit 122 is provided in preparation for a case where the correction of a duty ratio is not fully performed or where a duty ratio is twisted again after the duty ratio is corrected as described above.

For example, if the duty ratio of a clock is first twisted by +10 (where ‘+’ means that the width of a high pulse section is greater than that of a low pulse section) and a maximum duty ratio of a clock that may be corrected through one duty ratio correction operation is only +7, it may be impossible to fully correct the duty ratio of the clock through one duty ratio correction operation. In such case, the duty ratio of the clock may be fully corrected by correcting the duty ratio of the clock by +7 through a first duty ratio correction operation and then correcting the duty ratio of the clock by +3 through a second duty ratio correction operation.

Furthermore, if the duty ratio of a clock is first twisted by +5, the duty ratio of the clock may be fully corrected by controlling the duty ratio of the clock by +5 through one duty ratio correction operation. If the duty ratio is further twisted by +2 in an operation subsequent to the duty ratio correction operation, however, a value of the first duty ratio control code C_IN<1:5> needs to be set to +7 by further adjusting the duty ratio of the clock by +2 in addition to the existing +5. The accumulation unit 122 performs such a function.

The code filter unit 130 outputs the second duty ratio control code C_OUT<5:1> corresponding to a target valuer when a code value corresponding to the first duty ratio control code C_IN<5:1> is within a predetermined critical range (or dead zone) including a duty ratio target value. Here, the target value is a value when a duty ratio of the output clock CLK_OUT is 50%, and the critical range may be greater than or smaller than the target value by a specific size.

For example, the code filter unit 130 converts a code within a critical range (corresponding to a duty ratio of 49% to 51%) including a target value of 50%, among the first duty ratio control codes C_IN<1:5>, into a value of ‘0’, that is, a default code (or a locked code).

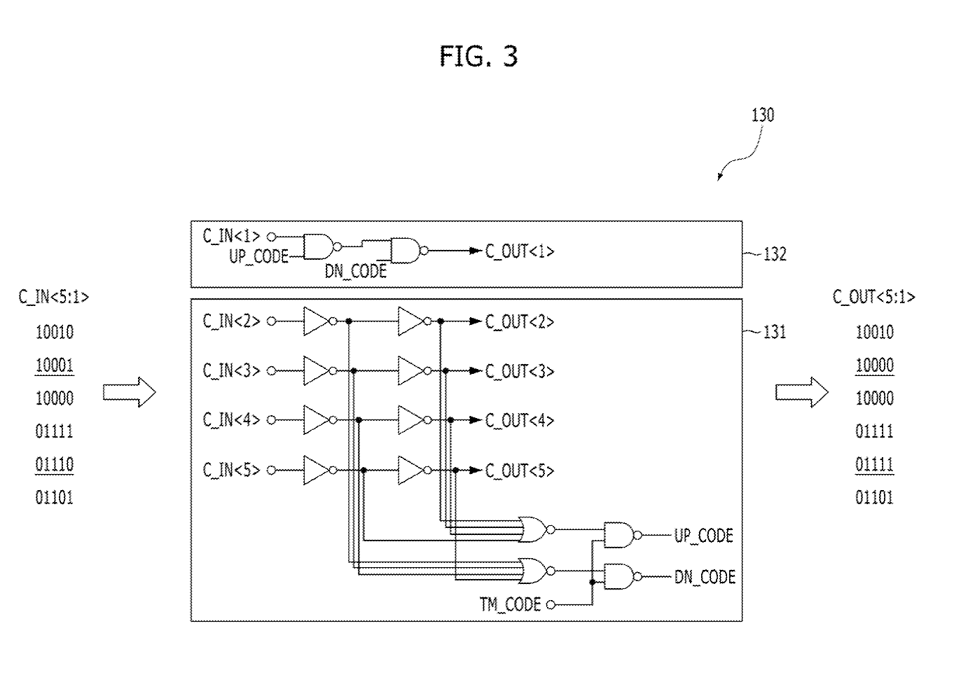

That is, when the first duty ratio control code C_IN<1:5> corresponding to a duty ratio close to 50% is received, the code filter unit 130 may perform an operation of outputting the second duty ratio control code C_OUT<1:5> corresponding to the duty ratio of 50%. A detailed construction of the code filter unit 130 is described later with reference to FIG. 3.

The duty ratio control unit 110 adjusts the duty ratio of the input clock CLK_IN based on the second duty ratio control code C_OUT<5:1> output from the code filter unit 130 and outputs the adjusted clock as the output clock CLK_OUT. The output clock CLK_OUT may be output by controlling the duty ratio of the input clock CLK_IN using the second duty ratio control code C_OUT<5:1> because the second duty ratio control code C_OUT<5:1> includes information indicating that a clock is twisted in which direction and how much the clock is twisted.

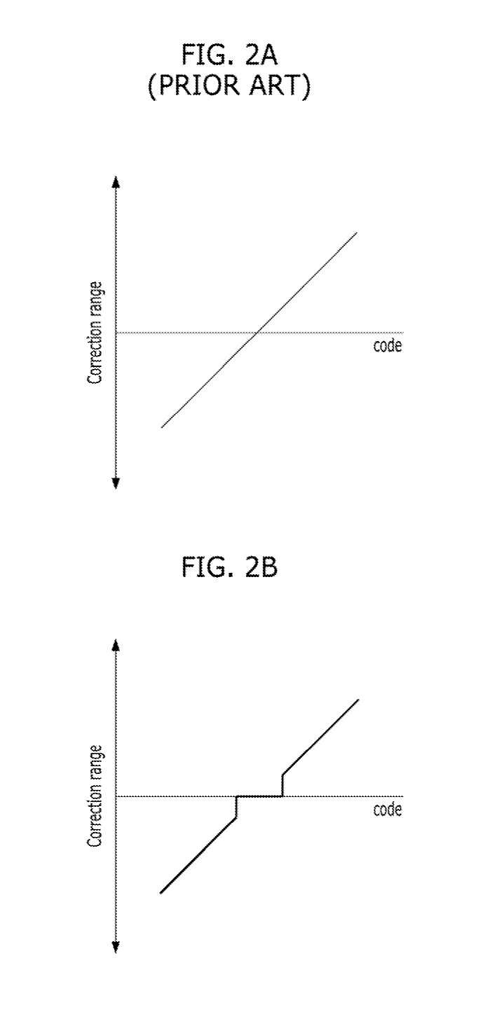

FIG. 2A is a graph showing a duty ratio correction range according to a code in a conventional DCC, and FIG. 2B is a graph showing a duty ratio correction range according to a code in a DCC in accordance with an embodiment of the present invention.

As in FIG. 2A, the conventional DCC has a linear characteristic in which the conventional DCC outputs ‘1’ when, for example, ‘1’ is received and outputs ‘2’ when, for example, ‘2’ is received. In contrast, as shown in FIG. 2B, the DCC in accordance with the embodiment of the present invention may output ‘0’, that is, a default code value, without considering an error to be an error although the error is generated within a critical range. That is, the code filter unit 130 outputs a code corresponding to a target value when a clock within a critical range is received, by presetting a dead zone.

Accordingly, a duty ratio may be prevented from being twisted by a bang-bang phenomenon in which a clock has a duty ratio that goes up and down within a critical range including a target value.

FIG. 3 is a detailed diagram of the code filter unit 130 shown in FIG. 1.

Referring to FIGS. 1 and 3, the code filter unit 130 generates the second duty ratio control code C_OUT 5:1> by converting a value of the first duty ratio control code C_IN<5:1> into a code corresponding to a target value when the value of the first duty ratio control code C_IN<5:1> is within a predetermined critical range.

The code filter unit 130 may include a code comparison unit 131 and an error code output unit 132.

The code comparison unit 131 receives the first duty ratio control code (or input code) C_IN<5:1> generated from the code generation unit 120, determines whether or not a value of the input code C_IN<5:1> is within the critical range including a target value, and outputs comparison codes UP_CODE and DN_CODE.

The error code output unit 132 receives the least significant bit C_IN<1> of the input code C_IN<5:1> and outputs an error code C_OUT<1> in response to the comparison codes UP_CODE and DN_CODE. The error code output unit 132 may include two NAND gates.

An upper 4-bit code C_IN<5:2> of the input code C_IN<5:1> is output as an upper 4-bit output code C_OUT<5:2> of the second duty ratio control code (or output code) C_OUT<5:1> and the comparison codes UP_CODE and DN_CODE through inverters, NOR gates, and NAND gates within the code comparison unit 131. Here, a value of the most significant bit code C_IN<5>, from among the 4 bits of the input code C_IN<5:2>, determines a default code value, and the 3 bits of a middle code C_IN<4:2> indicate an error size (or degree). If three bits of the middle code C_IN<4:2> are the same, such as ‘000’ or ‘111’, the comparison codes UP_CODE and DN_CODE have different values. In this case, it is determined that there is no error although the error is present. The comparison codes UP_CODE and DN_CODE output are input to the error code output unit 132, and the least significant bit code C_IN<1> of the input code C_IN<5:1> is controlled in response to the comparison codes UP_CODE and DN_CODE so that a value of the error code C_OUT<1> is output. Here, the output error code C_OUT<1> corresponds to a case not having an error and outputs a default code value.

That is, if three bits of the middle code C_IN<4:2> of the input code C_IN<5:1> are the same, such as ‘000’ or ‘111’, it is determined that there is no error although the error is present, and thus a default code value is output. In contrast, if three bits of the middle code CJN<4:2> have different values other than ‘000’ or ‘111’, an input code is output without converting an error code into a default code.

The default code value may be determined by a value of the most significant bit code C_IN<5> of the input code C_IN<5:1> as described above. If a value of the most significant bit code C_IN<5> is ‘1’, the default code value may be ‘0’. If a value of the most significant bit code C_IN<5> is ‘0’, the default code value may be ‘1’.

For example, if values of the input code C_IN<5:1> are ‘10001’, a value of the most significant bit code C_IN<5> of the input code C_IN<5:1> is ‘1’ and all the middle code C_IN<4:2> have the same values, that is, ‘000’. Accordingly, the error code C_OUT<1> is output as a value ‘0’ (i.e., the value), and thus the final output code C_OUT<5:1> becomes a value of ‘10000’. Similarly, if values of the input code C_IN<5:1> are ‘01110’, values of the output code C_OUT<5:1> become ‘01111’.

As described above, since the code filter unit 130 is included in the DCC 100, a duty ratio may be prevented from being twisted due to a bang-bang phenomenon occurring when a clock has a duty ratio within a critical range close to a 50% duty ratio.

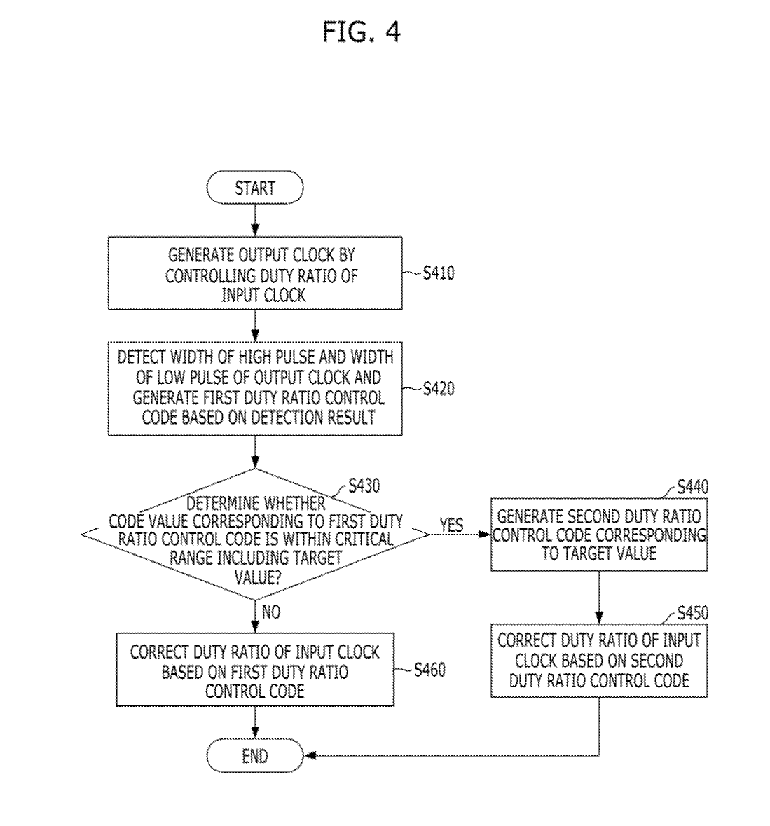

FIG. 4 is a flowchart for explaining an operation of DCC shown in FIG. 1.

Referring to FIGS. 1 and 4, the duty ratio control unit 110 generates the output clock CLK_OUT by controlling the duty ratio of the input clock CLK_IN at step S410.

The code generation unit 120 detects the width of a high pulse section and the width of a low pulse section of the output clock CLK_OUT and generates the first duty ratio control code C_IN<5:1> based on the detection result at step S420.

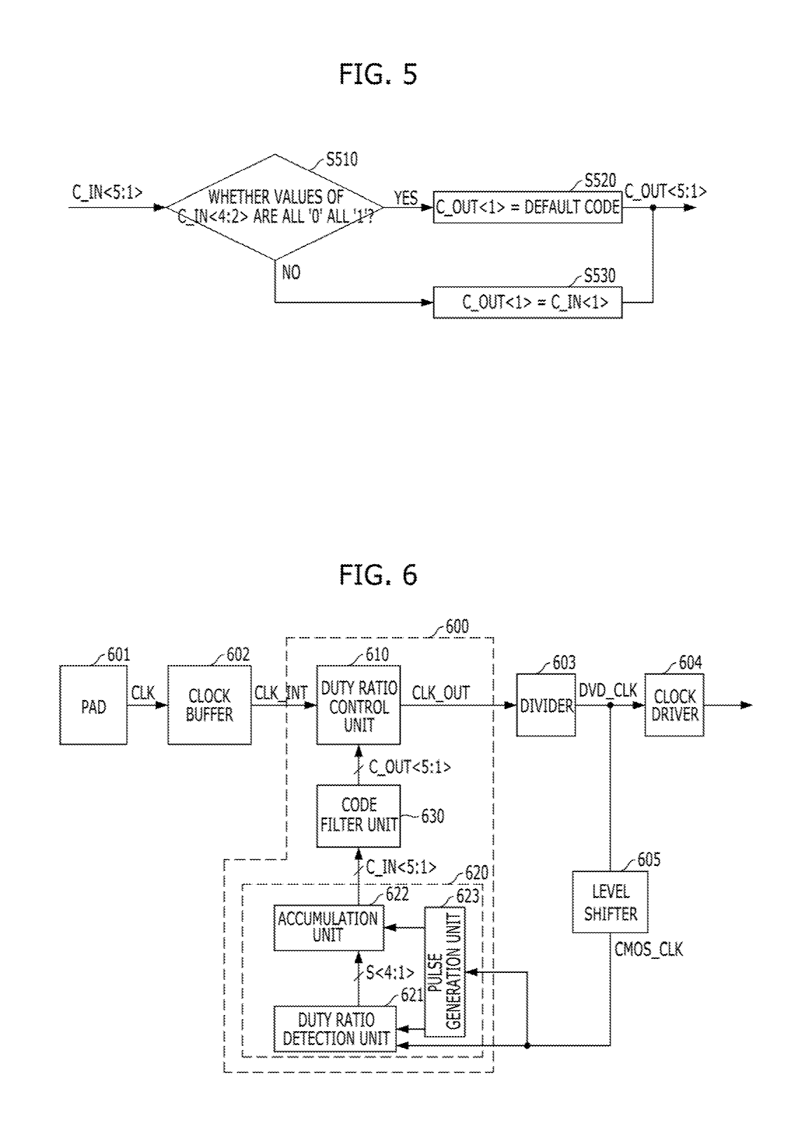

Next, the code filter unit 130 may determine whether or not a code value corresponding to the first duty ratio control code C_IN 5:1> is within a critical range including a target value at step S430. If, as the determination result, it is determined that a value of the first duty ratio control code C_IN<5:1> is within the critical range including the target value (i.e., Yes), the code filter unit 130 outputs the second duty ratio control code C_OUT<5:1> corresponding to the target value at step S440. The duty ratio control unit 110 may correct the duty ratio of the input clock CLK_IN using the second duty ratio control code C_OUT<5:1> generated as described above at step S450. Here, a detailed operation of generating the second duty ratio control code C_OUT<5:1> through steps S430 and S440 is described with reference to FIG. 5.

If, as the determination result, it is determined that a value of the first duty ratio control code C_IN<5:1> is within the critical range including the target value (i.e., No), the second duty ratio control code C_OUT<5:1> is output as a value of the first duty ratio control code C_IN<5:1> without converting at step S460. The duty ratio control unit 110 may correct the duty ratio of the input clock CLK_IN in response to the first duty ratio control code C_IN<5:1>.

FIG. 5 is a flowchart illustrating an operation of the code filter unit 130 shown in FIGS. 1 and 3.

Referring to FIGS. 1, 3, 4, and 5, the code filter unit 130 receives the first duty ratio control code (or the input code) C_IN<5:1> generated from the code generation unit 120 and checks whether values of the middle code C_IN<4:2> of the duty ratio control code C_IN<5:1> are all ‘0’ or all ‘1’ at step S510. Here, whether or not a code value corresponding to the input code C_IN<5:1> is within a predetermined critical range including a target value may be checked (i.e., the step S510 corresponds to the step S430).

That is, if a value of the middle code C_IN<4:2> is ‘000’ or ‘111’ (i.e., Yes) the code filter unit 130 determines that the code value corresponding to the input code C_IN<5:1> is within the critical range and outputs an output value of the least significant bit code C_OUT<1> of the second duty ratio control code (or the output code) C_OUT<5:1> as a default code value corresponding to the target value at step S520. Here, a value of the most significant bit code C_IN<5> of the input code C_IN<5:1> determines the default code value. If a value of the most significant bit code C_IN<5> is ‘1’, the default code value is output as ‘0’. If a value of the most significant bit code C_IN<5> is ‘0’, the default code value is output as ‘1’.

As described above, the output code C_OUT<5:1> corresponding to the target value may be generated at step S520 (i.e., the step S520 corresponds to the step S440).

If a value of the middle code C_IN<4:2> of the input code C_IN<5:1> is not ‘000’ or ‘111’ at step S510 (i.e., No), a value of the least significant bit code C_OUT<1> of the output code C_OUT<5:1> is output as the same value as that of the least significant bit code C_IN<1> of the input code C_IN<5:1> not a default code value at step S530.

Accordingly, a value of the least significant bit code C_IN<1> is controlled in response to a value of the least significant 4-bit code C_IN<5:2> of the input code C_IN<5:1> and thus the duty ratio control code C_OUT<5:1> may be finally output.

FIG. 6 is a block diagram illustrating a semiconductor device including the DCC in accordance with the embodiment of the present invention.

Referring to FIG. 6, a semiconductor device may include a DCC 600, a pad 601, a clock buffer 602, a divider 603, a clock driver, and a level shifter 605.

Here, the DCC 600 may include a duty ratio control unit 610, a code generation unit 620, and a code filter unit 630. The DCC 600 including the elements corresponds to the DCC of FIG. 1, and thus a detailed description of the elements of the DCC 600 is omitted.

The clock buffer 602 receives an external clock CLK through a pad 601 and generates an internal clock CLK_INT. The internal clock CLK_INT corresponds to the input clock CLK_IN described above.

The divider 603 operates in a current-mode logic (CML) level. The divider 603 acts as a voltage divider or a frequency divider, on the output clock CLK_OUT.

The clock driver 604 drives an output clock DVD_CLK generated from the divider 603 to an internal circuit (not shown).

The level shifter 605 changes the clock DVD_CLK operating in the CML level, into a CMOS level.

Here, the duty ratio control unit 610 has been illustrated as controlling the duty ratio of a clock that swings in a CML level, and thus related elements have been shown in FIG. 6. It is to be noted that such elements are not essential in the DCC because whether the duty ratio control unit 610 may control the duty ratio of a clock that swings in the CMOS level or the duty ratio of a clock that swings in the CML level is optional depending on circumstances.

The code generation unit 620 may include a pulse generation unit 623, a duty ratio detection unit 621, and an accumulation unit 622.

The pulse generation unit 623 of the code generation unit 620 of the DCC 600 generates a pulse using a clock signal CMOS_CLK converted to have a CMOS level through the level shifter 605 and transfers the pulse to the duty ratio detection unit 621 and the accumulation unit 622. In response to the pulse, the duty ratio detection unit 621 and the accumulation unit 622 may perform respective operations every cycle in which the pulse signal is updated.

In accordance with the embodiment of the present invention, the width of a high pulse section and the width of a low pulse section may be detected every update cycle and a duty ratio may be directly corrected using a difference between the detected values. In the case of the ideal operation, a duty ratio may be corrected through one update cycle operation, and even when not in the case of the ideal operation, a duty ratio may be corrected while reducing a locking time.

Furthermore, if a clock has a duty ratio within a critical range close to a 50% duty ratio, the duty ratio may be prevented from being twisted due to a bang-bang phenomenon.

In the aforementioned embodiments, a critical range has been set using a 50% duty ratio as a target value, but this is only an embodiment. A target value may be changed if necessary, and thus a critical range may be changed based on the changed target value.

In the aforementioned embodiments, an example in which the code filter unit 130 is formed of NOR gates and NAND gates has been described, but the present invention may also be applied to an example in which the code filter unit 130 is formed of other types of logic gates. Furthermore, in the aforementioned embodiments, the locations and types of the illustrated logic gates may be differently implemented depending on the polarity of an input signal.

The DCC in accordance with the aforementioned embodiments detects the width of a high pulse section and the width of a low pulse section every update cycle and directly corrects a duty ratio using the difference between the detected values. Accordingly, a locking time may be reduced.

Furthermore, since the width of a high pulse section and the width of a low pulse section are detected using the same construction and only the difference between the detected values is used, an offset generated when detecting the width of a high pulse section and the width of a low pulse section may be removed.

Furthermore, when a signal having a duty ratio close to 50% is received, a duty ratio may be prevented from being twisted due to a bang-bang phenomenon in which a duty ratio goes up and down on the basis of a 50% duty ratio.

While the present invention has been described with respect to the specific embodiments, it will be apparent to those skilled in the art that various changes and modifications may be made without departing from the spirit and scope of the invention as defined in the following claims.

What is claimed is:

1. A duty correction circuit, comprising:
a duty ratio control unit suitable for generating an output clock by adjusting a duty ratio of an input clock;
a code generation unit suitable for detecting a duty of the output clock and generating a first duty ratio control code based on the detection result; and
a code filter unit suitable for providing the duty ratio control unit with a second duty ratio control code corresponding to a target value when a value of the first duty ratio control code is within a predetermined critical range adjacent to the target value.

2. The duty correction circuit of claim 1, wherein the code filter unit comprises:
a code comparison unit suitable for generating comparison codes by determining whether or not the value of the first duty ratio control code is within the predetermined critical range; and
an error code output unit suitable for outputting an error code of the second duty ratio control code based on the comparison codes.

3. The duty correction circuit of claim 2, wherein the code filter unit generates the second duty ratio control code by converting the first duty ratio control code into a default value if, as the determination result, it is determined that the output clock has a duty ratio within the predetermined critical range.

4. The duty correction circuit of claim 2, wherein the comparison codes are generated using a combination of upper 4-bit codes of the first duty ratio control code.

5. The duty correction circuit of claim 4, wherein the default value is determined depending on a value of a most significant bit code of the 4-bit codes.

6. The duty correction circuit of claim 5, wherein if lower 3-bit codes of the 4-bit codes have an identical value, a least significant bit of the first duty ratio control code is output as the default value.

7. The duty correction circuit of claim 1, herein the code generation unit comprises:
a duty ratio detection unit suitable for detecting a difference between a width of a high pulse section and a width of a low pulse section of the output clock every update cycle and generating a duty ratio detection code corresponding to the detected value; and
an accumulation unit suitable for generating the first duty ratio control code by accumulating values of the duty ratio detection code output every update cycle.

8. The duty correction circuit of claim 7, wherein the duty ratio detection unit further outputs an up/down signal, indicating which one of the width of the high pulse section and the width of the low pulse section is greater.

9. The duty correction circuit of claim 8, wherein the accumulation unit adds up or subtracts the values of the duty ratio detection code to or from an existing duty ratio control code in response to the up/down signal.

10. A duty ratio duty correction method, comprising:
detecting a duty of an output clock;
generating a first duty ratio control code based on the detection result;
outputting a second duty ratio control code corresponding to a target, value when a value of the first duty ratio control code is within a predetermined critical range adjacent to the target value; and
adjusting the duty ratio of an input clock based on the second duty ratio control code and outputting the adjusted clock as the output clock.

11. The duty ratio duty correction method of claim 10, wherein the outputting of the second duty ratio control code comprises:
determining whether or not the value of the first duty ratio control code is within the predetermined critical range; and
outputting the second duty ratio control code based on the determination result.

12. The duty ratio duty correction method of claim 11, wherein the outputting of the second duty ratio control code comprises:
generating the second duty ratio control code by converting the first duty ratio control code into a default value if, as the determination result, it is determined that the output clock has a duty ratio within the predetermined critical range.

13. The duty ratio duty correction method of claim 12, wherein the determination result is generated using a combination of upper 4-bit codes of the first duty ratio control code.

14. The duty ratio duty correction method of claim 13, wherein the default value is determined depending on a value of a most significant bit code of the 4-bit codes.

15. The duty ratio duty correction method of claim 14, wherein the second duty ratio control code is output as the default value when lower 3-bit codes of the 4-bit codes have an identical value.

16. The duty ratio duty correction method of claim 10, wherein the generating of the first duty ratio control code comprises:
detecting a difference between a width of a high pulse section and a width of a low pulse section of the output clock and generating a duty ratio detection code corresponding to the detected value; and
generating the first duty ratio control code by accumulating values of the duty ratio detection code output every update cycle.
